(19) United States
(12) Patent Application Publication
(10) Pub. No.: US 2002/0190285 A1
(43) Pub. Date: Dec. 19, 2002

(54) Power supply apparatus using power semiconductor switching element

(76) Inventors: Kozo Sakamoto, Hitachinaka (JP); Eiji Yanokura, Takasaki (JP); Masaki Shiraishi, Hitachi (JP); Takayuki Iwasaki, Hitachi (JP)

Correspondence Address: DICKSTEIN SHAPIRO MORIN & OSHINSKY LLP, 2101 L STREET NW, WASHINGTON, DC, 20037-1526, US

(21) Appl. No.: 10/188,028

(22) Filed: Jul. 3, 2002

Related U.S. Application Data
(63) Continuation of application No. 10/067,746, filed on Feb. 8, 2002.

(30) Foreign Application Priority Data
Jun. 4, 2001 (JP) 2001-167561

(51) Int. Cl. H01L 29/76

(52) U.S. Cl. 257/288

(57) ABSTRACT

The on-resistance per chip area of a horizontal power MOSFET is reduced. In the horizontal power MOSFET in accordance with the present invention, low resistance penetrating conductive zones penetrating from a semiconductor surface in a p-type semiconductor zone on a low resistance p-type semiconductor substrate connected to an outer source electrode up to the p-type semiconductor zone are formed, and two or more n-type drain zones electrically connected to drain electrodes are formed in a semiconductor zone surrounded by the low resistance penetrating conductive zones, and an outer drain zone is provided on an active zone.

This is a continuation of U.S. patent application Ser. No. 10/067,746, filed Feb. 8, 2002, the entire disclosure of which is incorporated herein by reference.

### BACKGROUND OF THE INVENTION

The present invention relates to a high-frequency-capable power semiconductor device, and particularly to lowering of on resistance of a high-frequency-capable power MOSFET and a power supply circuit system using the high-frequency-capable power MOSFET.

A vertical power MOSFET having excellent low on-resistance property has been mainly used in a DC/DC power supply circuit for a personal computer, a VRM and so on. However, in order to improve the power supply efficiency, not only the low on-resistance property required until now, but reducing of feedback capacitance also becomes to be required. For example, in the case of a back type power supply circuit, reducing of feedback capacity is necessary for improving high efficiency in order to reduce switching loss in an upper side power MOSFET.

Although there is a horizontal power MOSFET as a structure capable of reducing feedback capacitance, there is a problem that the on resistance per chip area is difficult to be reduced. Particularly, in a case of a horizontal power MOSFET using its substrate as the source electrode, it is further difficult to reduce the on-resistance per chip area because an area of the low resistance perforating diffusion layer for connecting between the semiconductor back-side surface and the semiconductor front-side surface in low resistance is large.

A method of reducing the on-resistance per chip area in the horizontal power MOSFET is disclosed in Japanese Patent Application Laid-Open No.6-232396. The method is that a p-type perforating diffusion layer portion serving by using the low resistance perforating diffusion layer described above as a current path between a low resistance source substrate and the semiconductor surface is separated from the source layer, and formed in an area equivalent to a given resistance value, and connected to the source layer with a metallic wire.

In Japanese Patent Application Laid-Open No.6-232396 described above, there is an idea of reducing the p-type perforating diffusion layer portion in order to reduce the on-resistance per chip area, but there is no concrete proposal on the plain surface structure and the cross-sectional surface structure including a detailed electrode wiring structure when the p-type perforation diffusion layer portion is removed from the source layer. Therefore, there is a problem in that the on-resistance can not always be reduced. Further, there is no sufficient discussion on the method of reducing the parasitic resistance of the conventional power transistor having a drain withstanding voltage specification of 30 V or lower and the mounting method.

Furthermore, there is no sufficient discussion on the effective connection method of a schottky diode for improving the efficiency of the power supply circuit by preventing operation of the parasitic diode of the power MOSFET.

The present invention is made in taking the above-mentioned problems into consideration, and relates to the feedback capacity and the on-resistance of the power semiconductor device. An object of the present invention is to provide a method of improving an efficiency of a circuit using a power semiconductor device.

### SUMMARY OF THE INVENTION

The outline of the semiconductor device in accordance with the present invention is listed as follows.

(1) Two or more drain zones are provided between low resistance perforating diffusion layers 3 of a horizontal power MOSFET to form a multi-drain type element.

(2) The plane layout of a first electrode layer 12a is completely reformed in order to materialize the multi-drain horizontal power MOSFET.

(3) The horizontal power MOSFET has a drain pad on an active zone.

(4) The low resistance perforating conductive zone is a low resistance p-type semiconductor zone, or is formed by forming a silicon groove having a small plane size and embedding a long thin poly-crystalline silicon layer or a long thin metal layer in the groove.

(5) Lead wires are electrically connected to an outer terminal zone through bump electrodes or a conductive adhesive so as to cover over a main active zone. Particularly, as a means connecting the power transistor and a schottky diode in parallel, they are connected by adjacently placing.

(6) Transistors are connected by vertically putting one another through bumps.

(7) A pre-driver transistor is placed together with the power transistor on a single chip.

(8) An input of the chip of the power transistor and output terminal of a control IC are connected by a lead wire using a bump at an outer gate terminal or an outer input terminal.

(9) A metal or a metallic compound is embedded in at least a part of the low resistance semiconductor substrate so that resistance in the thickness direction of the low resistance semiconductor substrate is decreased.

(10) The power transistor has a withstanding voltage lower than 100 V, and the low resistance semiconductor substrate has a thickness thinner than 60 m.

According to the semiconductor device in accordance with the present invention, a power semiconductor device such as a power transistor or the like can be made low in loss and low in capacity, and further, can reduce the ill influence caused by parasitic impedance. In addition, a power supply circuit can be improved by using the power transistor in accordance with the present invention.

### BRIEF DESCRIPTION OF THE DRAWINGS

FIG. 1 is a cross-sectional view of a first embodiment of a power semiconductor device.

FIG. 2 is a plan view of the first embodiment of the power semiconductor device.

FIGS. 3(a) and 3(b) are cross-sectional views of the first embodiment of the power semiconductor device.

FIG. 4 is a circuit diagram of a second embodiment of a power semiconductor device.

FIG. 5 is a circuit diagram of a third embodiment of a power semiconductor device.

FIG. 6 is a plan view of a fourth embodiment of a power semiconductor device.

FIGS. 7(a) through 7(c) are cross-sectional views of the fourth embodiment of the power semiconductor device.

FIG. 8 is a cross-sectional view of a fifth embodiment of a power semiconductor device.

FIG. 9 is a cross-sectional view of a sixth embodiment of a power semiconductor device.

### PREFERRED EMBODIMENTS OF THE INVENTION

Power supply devices in accordance with the present invention will be described below in detail, referring to the accompanied drawings.

<Embodiment 1>

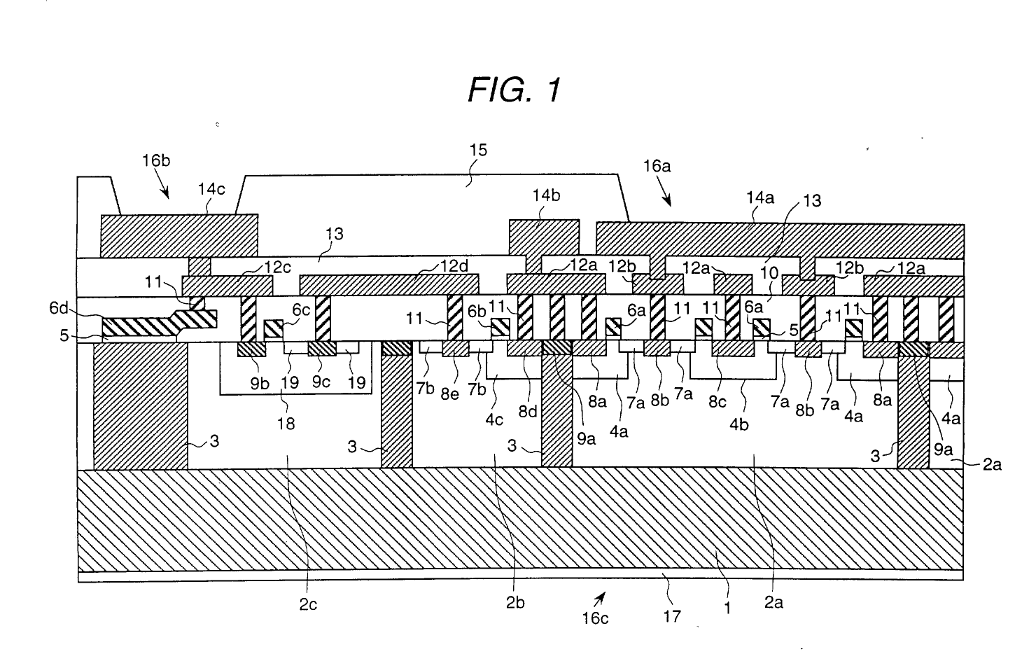

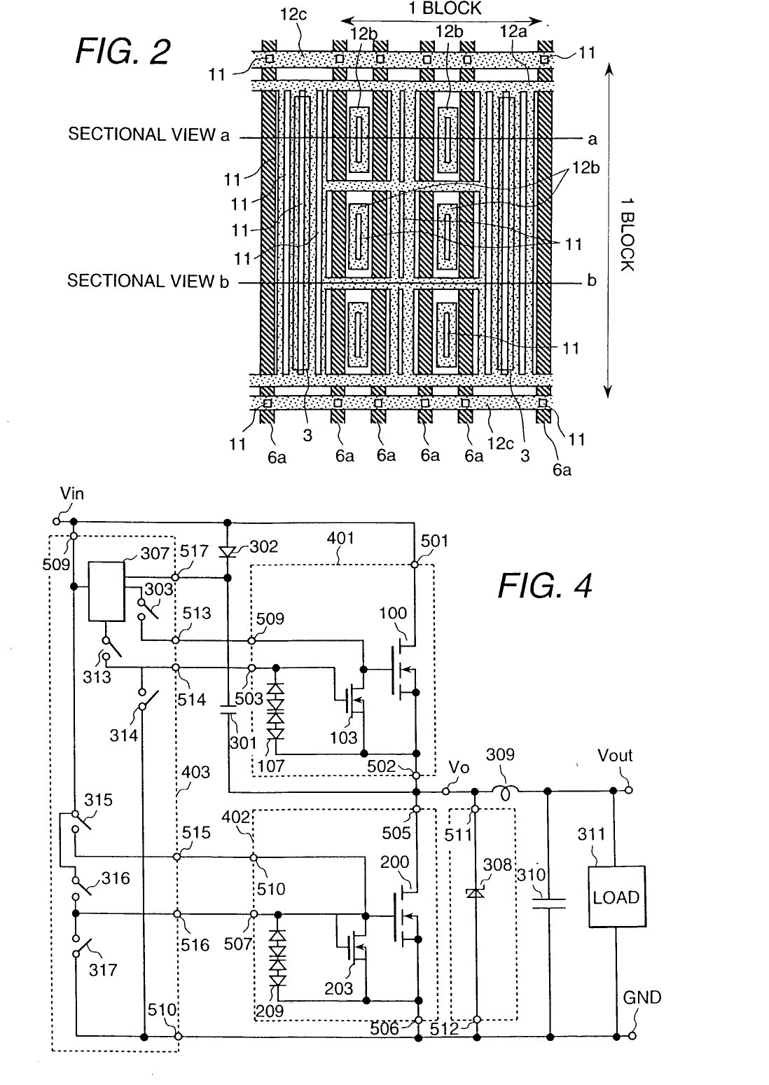

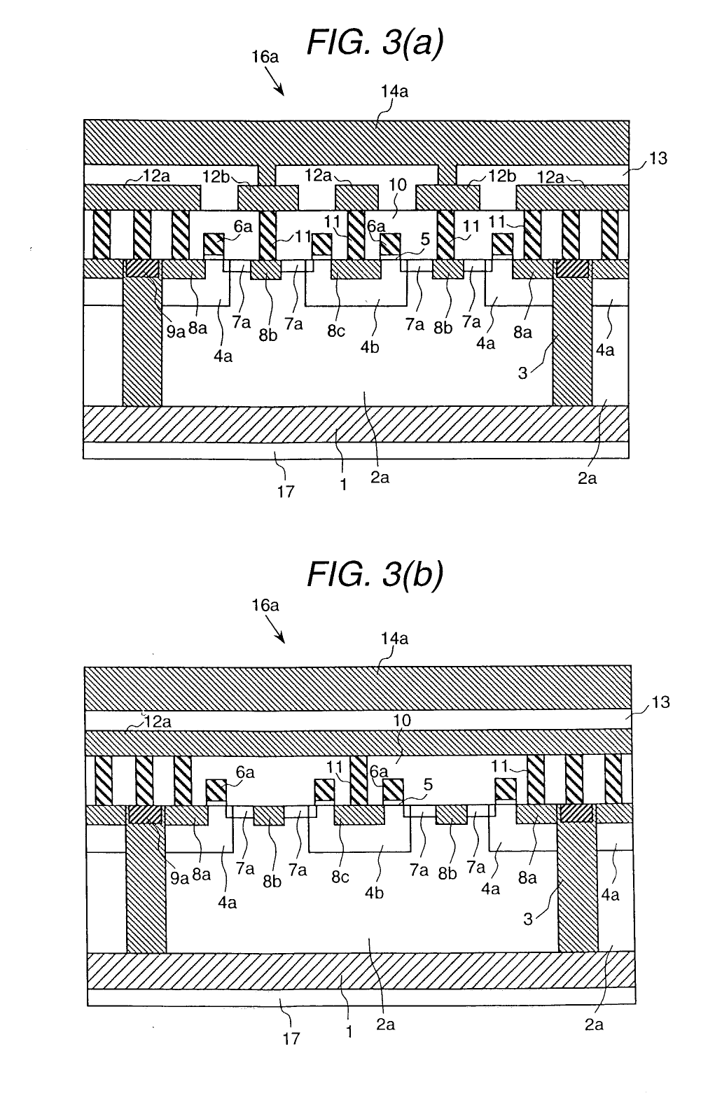

FIG. 1 is a cross-sectional view of an embodiment of a power semiconductor device, and FIG. 2 shows the plan view, and FIG. 3 shows cross-sectional views being taken on the planes of the line a-a and the line b-b of the plan view of FIG. 2. As shown in FIG. 1 to FIG. 3, a p-type epitaxial layer 2a having a resistance higher than a p-type semiconductor substrate 1 is placed on the p-type semiconductor substrate 1 if a low resistant substrate connected to a reverse surface electrode 17, and low resistance penetrating diffusion layers 3 penetrating from the semiconductor surface to the p-type semiconductor substrate 1 are formed in the p-type epitaxial layer 2, and an n-type source zone 8a formed adjacent to the low resistance penetrating diffusion layer 3 and an n-type source zone 8c formed apart from the low resistance penetrating diffusion layer 3 are formed in the p-type epitaxial layer 2a surrounded by the low resistance penetrating diffusion layers 3. The reference character 8b indicates an n-type drain zone.

As shown in FIG. 2 and FIG. 3(b), the n-type source zone 8c formed apart from the low resistance penetrating diffusion layer 3 is connected to the low resistance penetrating diffusion layer 3 through a tungsten plug 11 and a first electrode layer 12a. The n-type drain zone 8b is connected to a second electrode layer 14a through the tungsten plug 11 and the first electrode layer 12b, and is a second electrode layer 14a portion not coated with a preventive film 15, that is, the portion 16a is an electrode pad serving as an outer drain electrode. An electrode pad 16c is formed on an active zone having transistor-operated gate electrodes 6a arranged thereon through an insulation layer 10.

In the horizontal power transistor of the prior art, the first electrode layer 12b on the n-type drain zone 8b and the gate electrode 6a are wired by extending up to the outside of the active zone to provide a drain electrode pad and a gate electrode pad outside of the active zone. Therefore, the drain resistance is increased because the first electrode layer 12a of the drain electrode is extended thin and long, and further the active zone becomes smaller due to a space for the drain pad zone. On the other hand, in the present embodiment, the drain resistance can be reduced.

In the structure of the horizontal transistor, the drain-gate capacitance is small, but there has been a problem in that the on resistance per unit area is difficult to be reduced because the low resistance perforating diffusion layer 3 is generally formed through a diffusion process and accordingly the diffusion progresses in the horizontal direction as well as in the vertical direction.

In the present embodiment, by the new method of wiring from the n-type source zone 8c formed apart from the low resistance perforating diffusion layer 3 to the first electrode layer 12a of the source electrode as described above, the two n-type drain zones 8b can be arranged between the low resistance perforating diffusion layers 3 whereas in the prior art only one n-type drain zone can be arranged between the low resistance perforating diffusion layers 3. Further, in the present embodiment the three source zones can be arranged between the low resistance perforating diffusion layers 3 (one source diffusion zone not adjacent to the low resistance perforating diffusion layer 3 is increased) whereas in the prior art only two of the source zones can be arranged between the low resistance perforating diffusion layers 3. Therefore, the width per unit area of the gate of MOSFET can be increased to reduce the on resistance. Although the present embodiment shows the case where the three source zones and the two drain zones are formed between the low resistance perforating diffusion layers 3, it is possible that five source zones and three drain zones are similarly arranged, or that more number of the source zones and more number of the drain zones are arranged.

The present embodiment shows the case where the three source zones (the one source diffusion zone not adjacent to the low resistance perforating diffusion layer 3) are arranged between the low resistance perforating diffusion layers 3. However, if number of the n-type source zones 8c not adjacently provided with the low resistance perforating diffusion layer 3 is increased, the resistance components of the low resistance perforating diffusion layer 3 and the n-type drain zone 8b (current flows in the depth direction of FIG. 2) and the resistance component of the first electrode layer 12a of the source are increased though the channel resistance is increased. Therefore, in a case where the drain withstanding voltage is about 30 V to 40 V or smaller, there generally exists a minimum value of the on resistance per unit area within a range in one to three of the n-type source zones 8c not adjacently provided with the low resistance perforating diffusion layer 3.

The n-type drain zone 8b and the source electrode and the p-type zone 4a are p-well zones, and are formed under the gate electrode layer 5 together with the n-type source zones 8a, 8c in order to control the threshold voltage. Further, the reference characters 11a˜11d are tungsten plugs, and the second electrode layer 14 is formed on the tungsten plugs through the first electrode layer 12 and the insulation layer 13.

In the present embodiment, a low concentration n-type semiconductor zone 7 is provided adjacent to the n-type drain zone 8b in order to secure a high withstanding voltage between the drain and the source.

Further, the semiconductor device according to the present embodiment has the feature that by process-adding the n-channel POSFET (the gate electrode 6b, the source diffusion layer 8d, the drain diffusion layer 8a, the low concentration drain diffusion layer 7b) for turning off the power MOSFET, and further the n-well diffusion layer 18 and the low concentration p-type diffusion zone, the p-channel POSFET (the gate electrode 6c, the source diffusion layer 9d, the drain diffusion layer 9c, the low concentration drain diffusion layer 19) for turning on the power MOSFET and a capacitor using the gate electrode 6d can be formed on a single chip. Further, by arranging the capacitor under the electrode pad 16b, it is possible to prevent the occupied area from increasing.

The reference character 14b is a second electrode layer which is formed at the same time when the second electrode layers 14a and 14c are formed, and the second electrode layer 14b is arranged between the power transistor and the control MOSFET in order to reduce noises from the power transistor.

Although the present embodiment has been described taking the horizontal power MOSFET in the case of the p-type epitaxial layer 2a as an example, the same can be said on the horizontal power MOSFET in the case where the corresponding semiconductor layer is an n-type epitaxial layer.

<Embodiment 2>

FIG. 4 is a circuit diagram of an embodiment of a power semiconductor device. The power semiconductor device of the first embodiment can be used for an upper arm power MOSFET chip 401 or a lower arm power MOSFET chip 402 or the both chips. The circuit of the present embodiment a non-insulation type DC/DC power supply circuit of a buck-type power supply circuit which reduces an input voltage Vin of 48 V to 5 V to obtain an output voltage Vout of 5 V to 0.5 V. The reference character 311 is a load such as a microprocessor, and the reference character 309 is an inductance, and the reference character 310 is a capacitor. Power MOSFET chips 401 and 402 contain power MOSFETs 100 and 200, and also contain n-channel MOSFETs 103 and 203 and gate protection poly-crystalline silicon diodes 107 and 209, in the present embodiment.

Outer drain terminals are indicated by 501 and 505, and outer source terminals are indicated by 502 and 506, and outer gate terminals are indicated by outer terminals 509 and 510. External input terminals 503 and 507 for cutting off the power MOSFETs 100 and 200 are provided.

The reference character 403 is a control IC, and the reference characters 303 and 314 are switches for turning on the power MOSFET 100, and the reference character 313 is a switch for turning off the power MOSFET 100. The reference characters 315 and 317 are switches for turning on the power MOSFET 200, and the reference character 316 is a switch for turning off the power MOSFET 200, and the reference character 307 is a booster circuit for controlling gate voltage of the power MOSFET above Vin, and the reference characters 302 and 301 are a diode and a capacitor for a boot strap circuit. Therein, in a case where a power supply having a voltage higher than Vin can be used for turning on the upper arm power MOSFET 100, the diode 302, the capacitor 301 and the booster circuit 307 can be eliminated. The reference characters 509, 514, 515, 516 and 517 are outer terminals of the control IC 403.

When the horizontal power MOSFET of the first embodiment is used for the upper arm power MOSFET chip 401, the efficiency of the power supply can be improved because the feedback capacity is small and the on resistance is also low. Further, since the feedback capacity is small in the case where the horizontal power MOSFET of the first embodiment is used for the lower arm power MOSFET chip 402, when the drain voltage is rapidly increased, that is, when the power MOSFET 200 is turned off and the power MOSFET 100 is turned on, voltage of the internal gate terminal coupled with the capacitor between the drain and the gate is increased to prevent a self turn-on erroneous operation and accordingly the loss can be reduced. The self turn-on erroneous operation is a phenomenon that the power MOSFET is turned on even if the power MOSFET is tried to cut off from an external circuit. Therein, even in the case where the control n-channel MOSFETs 103 and 203 are not contained, high efficiency can be obtained.

Further, since the parasitic gate impedance can be reduced in the case where the n-channel MOSFETs 103 and 203 are mounted on the same chips of the power MOSFETs 100 and 200, the power MOSFETs 100 and 200 can be accurately off-controlled even if the driving frequency of the gate is increased. Therefore, the output voltage Vout can be stabilized and the output current flowing in the load can be stabilized, and accordingly the efficiency of the power supply can be improved.

<Embodiment 3>

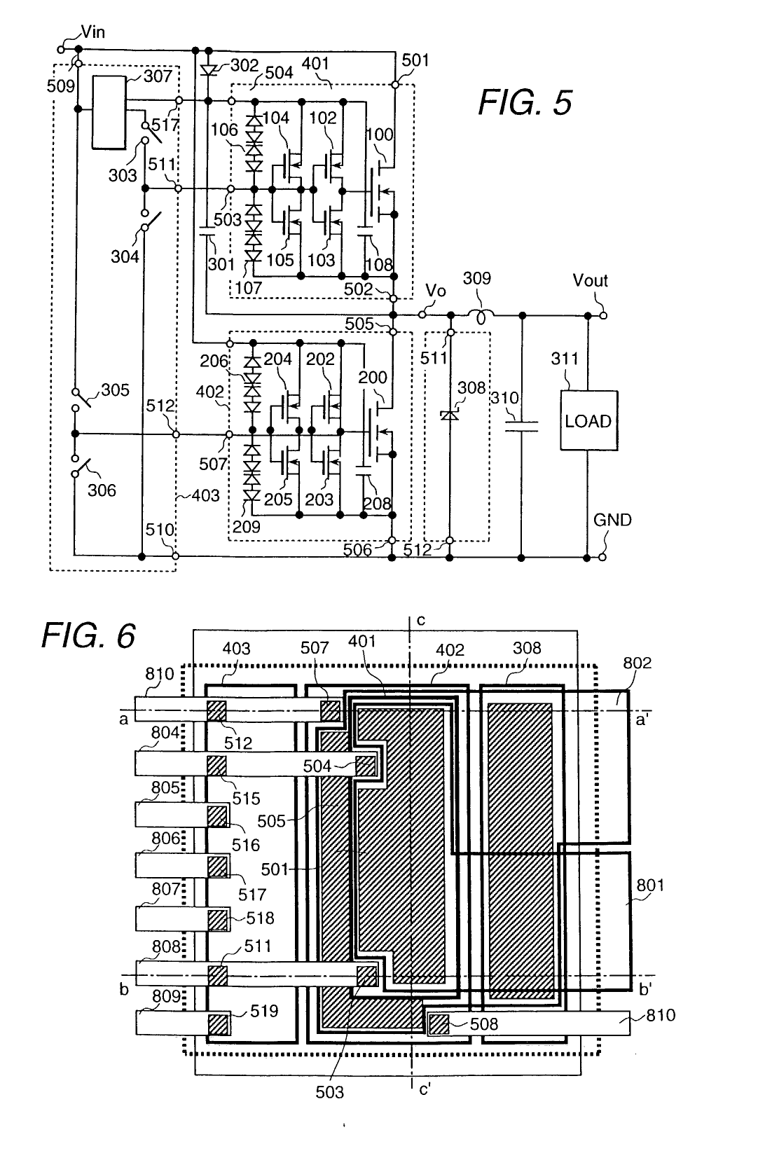

FIG. 5 is a circuit diagram of an embodiment of a power semiconductor device. The power semiconductor device of the first embodiment is used for either of an upper arm power MOSFET chip 401 or a lower arm power MOSFET chip 402, or the both chips.

A different point of the present embodiment from the second embodiment is that the p-channel MOSFETs 102, 104, 202 and 204 are contained in the power MOSFET chips to form a CMOS inverter circuit. Incidentally, it is preferable that the CMOS inverter circuit is made up by a plurality of stages (in this embodiment, two stages), and the ON/OFF control of the external input terminals 503 and 507 is made equal to that of the conventional and usual power MOSFET. Furthermore, it is preferable that although not shown in FIG. 5, high resistance elements are installed between the external terminal 503, 507 and the external source terminals 502, 506, which are housed within the power MOSFET chips 401, 402. In this case, an advantage occurs that the power MOSFET can be turned off when there are no signals to the external input terminals or the external input terminals are made to open state. By forming as described above, number of outer terminals of each of the power MOSFET chips can be reduced, and the structure of the control IC 403 can be made simple. Gate protection diodes 106 and 206 are added. Further, capacitors 108 and 208 are contained in the structure shown in FIG. 1. The capacitor is provided so as to stabilize the power supply voltage of the control MOSFET. It is preferable that each of the capacitors 108 and 208 has a capacitance larger than a gate capacitance of the power MOSFET. Therefore, when the thickness of the gate oxide film of each of the capacitors 108 and 208 is equal to the thickness of the gate oxide film, it is preferable that the area of the gate oxide film of the capacitor is larger than the area of the gate oxide film of the power MOSFET. The reference characters 509, 510, 511 and 512 are outer terminals of the control IC. The switches indicated by the reference characters 303 and 305 are used for raising the outer input terminals 503 and 507 of the power MOSFETs 401 and 402, respectively, and the switches indicated by the reference characters 304 and 306 are used for lowering the outer input terminals 503 and 507 of the power MOSFETs 401 and 402, respectively. In the present embodiment, two stages of CMOS circuits are contained in the power MOSFET chip in order to make the phase of the internal gate voltage of the power MOPSFET 100 or 200 equal to the phase of the outer gate terminal of the power MOSFET chip 401 or 402. This is because a signal of the control IC for driving a common power MOSFET is used. In a case where compatibility with the common power MOSFET is not required, one stage of the CMOS inverter may be used.

In the present embodiment, since the p-channel MOSFET is also formed on the same chip, the power MOSFET can be on-driven with low impedance, and further the power MOSFET can accurately be on-controlled even if the driving frequency of the gate is increased.

<Embodiment 4>

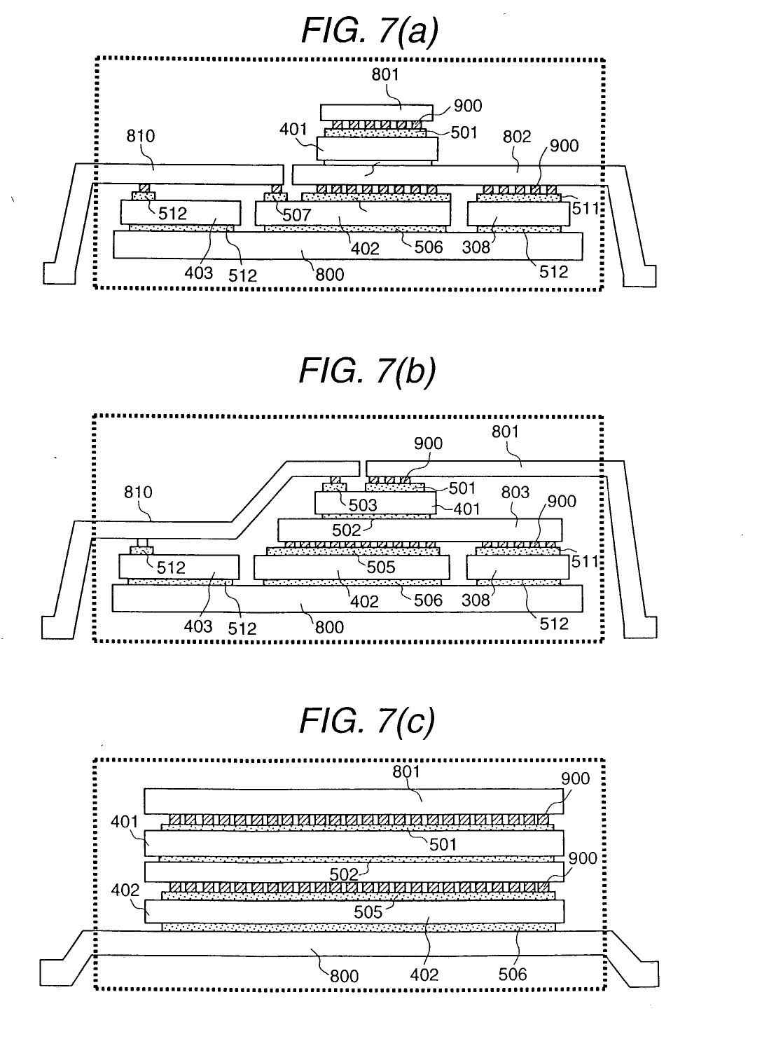

FIG. 6 and FIG. 7 are schematic views of the present embodiment of a power semiconductor device. The present embodiment shows a method of mounting the power MOSFET so as to reduce the parasitic resistance in taking the circuit shown in FIG. 4. FIG. 6 is the plan view, and FIG. 7 is cross-sectional views of the a-a′, b-b′ and c-c′ portions shown in FIG. 6.

In the present embodiment, both of the outer drain terminals 501, 505 and the outer source terminals 502, 506 of the power MOSFET chips 401 and 402 are face-contacted with a metal substrate of a conductive electrode 800 to be used as a ground through a conductive adhesive such as solder or conductive electrodes such as bumps 900, not using bonding wires of the prior art. Therein, each of the conductive electrodes 800, 801, 802 has a thickness above 0.2 mm and a maximum cross-sectional length above 1 mm. Further, all the main current outer terminals of the power semiconductor element of the outer drain terminals 501, 505 and the outer source terminals 502, 506 etc. are formed so as to cover at least 60% or more of an area of the active zone, that is, the zone performing transistor operation or rectifier operation.

Therefore, the resistance of the power MOSFET or the schottky diode can be reduced, and the ill influence due to the parasitic inductance can be reduced. Particularly, the schottky diode 308 connected to the power MOSFET 200 in parallel and the semiconductor chip are adjacently laid out, and are connected in low impedance using common conductive electrodes 800, 802 through the conductive adhesive such as solder or the conductive electrodes of bumps. In the prior art, an inductance having a significant magnitude is added to the power MOSFET 200 or the schottky diode 308 in series due to using of a bonding wire. Therefore, there is the problem in that the loss in the power supply circuit can not be reduced because switching between the power MOSFET 200 and the schottky diode 308 takes a long time. On the other hand, in the present embodiment, the loss can be reduced. The present embodiment describes the case where many elements are arranged inside a package. However, it is possible that only the power MOSFET 200 and the schottky diode 308 are enclosed in a single package, or that the power MOSFET 200 and the schottky diode 308 are formed on a single chip, and the power MOSFET 200 and the schottky diode 308 are connected to each other through the conductive adhesive such as solder or the conductive electrodes of bumps, not using any bonding wire.

Further, in the present embodiment, the control IC and the input terminal of the power transistor chip are connected in low impedance using the conductive electrodes 808, 810 through the conductive adhesive such as solder or the conductive electrodes of bumps. The reference characters 805, 806, 807 and 809 are lead wires (conductive electrodes) from the control IC, and are connected to the outer terminals 516, 517, 518 and 519 of the control IC through bumps, respectively. In this case, since a signal from the control IC transmitted in low impedance to the gate of the power MOSFET chip, erroneous operation or control delay hardly occurs even if no control circuit is contained in the power MOSFET chip.

The present embodiment relates to the method of wiring the power MOSFET 100 and the power MOSFET 200 which perform operation different from each other and contained in the single package. However, the method of vertically stacking and connecting the semiconductor chips using the bumps or the conductive adhesive and wiring using the low resistance plates such as lead wires shown by the present embodiment may be used for connecting outer terminals of two or more semiconductor chips in parallel inside a package. That is, the method can be used for connecting the outer drain terminals, the outer source terminals and the outer gate terminals of the power MOSFET chips in parallel inside the package. Similarly, the method can be used for connecting the outer anode terminals and the outer cathode terminals of the diodes in parallel inside the package. In this case, there is an effect in that the on-resistance can be reduced from the user's viewpoint without improving the on-resistance of the semiconductor element as the chip performance. Further, by thinning the silicon thickness of the transistor chips vertically stacked (for example, thinner than 100 m), it is possible to suppress increase of the thickness of the package.

<Embodiment 5>

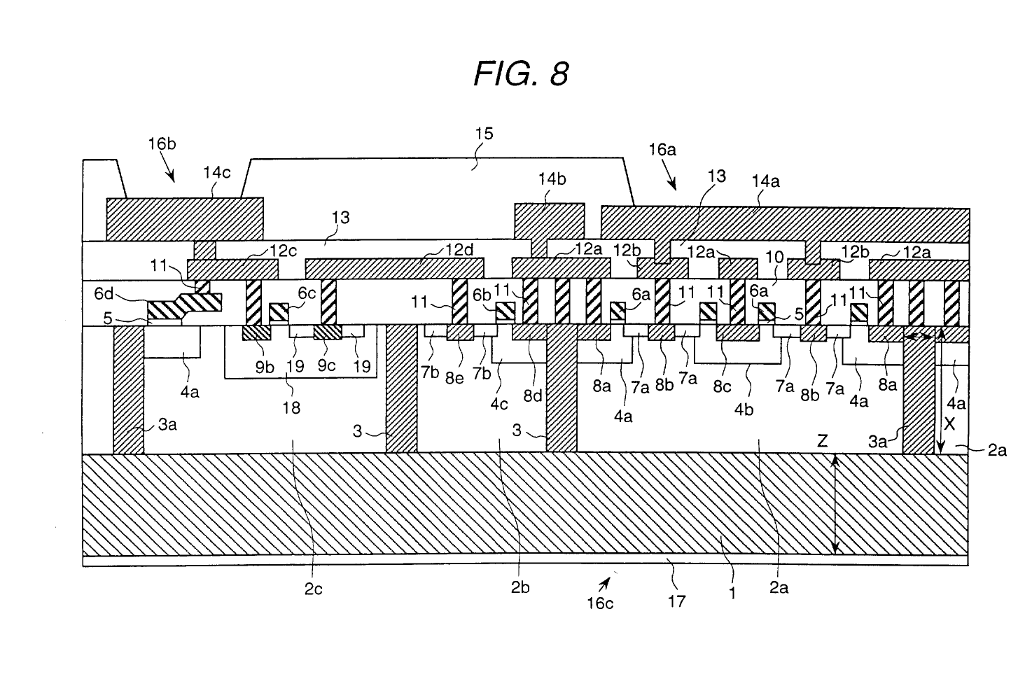

FIG. 8 is a circuit diagram of the present embodiment of a power semiconductor device. In the present embodiment, instead of the low resistance penetrating diffusion layer 3 of the first embodiment, a low resistance perforating zone 3a is used. The low resistance perforating zone 3a is formed by forming a narrow-width and deep groove in the silicon chip through anisotropic etching, and embedding impurity doped polycrystalline silicon into the groove. In this case, the on resistance per unit area can be further reduced because the dimension Y can be narrowed when the dimension X is constant. It is preferable that in order to further reduce the on resistance, the thickness Z of the p-type semiconductor substrate is thinned so that the thickness of the semiconductor chip becomes 60 m or thinner. This is effective when the on resistance of the power MOSFET is smaller than 3 m, or when the specification of the withstanding voltage between the drain and the source is lower than 30 V. This reason is that because the limit value up to now of specific resistance of the low resistance substrate in the case of silicon is 2˜3 m cm, the on-resistance components become out of balance unless the thick silicon substrate of 200 m thickness, which is applied to the power element of the prior art, is reduced to 60 m or thinner. Further, in a case of using a substrate difficult to reduce resistance such as an SiC substrate, since the specific resistance of the SiC substrate is five times as large as that of the silicon substrate, the specification effective for the SiC substrate having a thickness below 60 m is a case where the drain withstanding specification is below 300 V. Furthermore, in order to make the drain withstanding voltage below 30 V, it is necessary to make the effective thickness of the SiC substrate below 12 m.

<Embodiment 6>

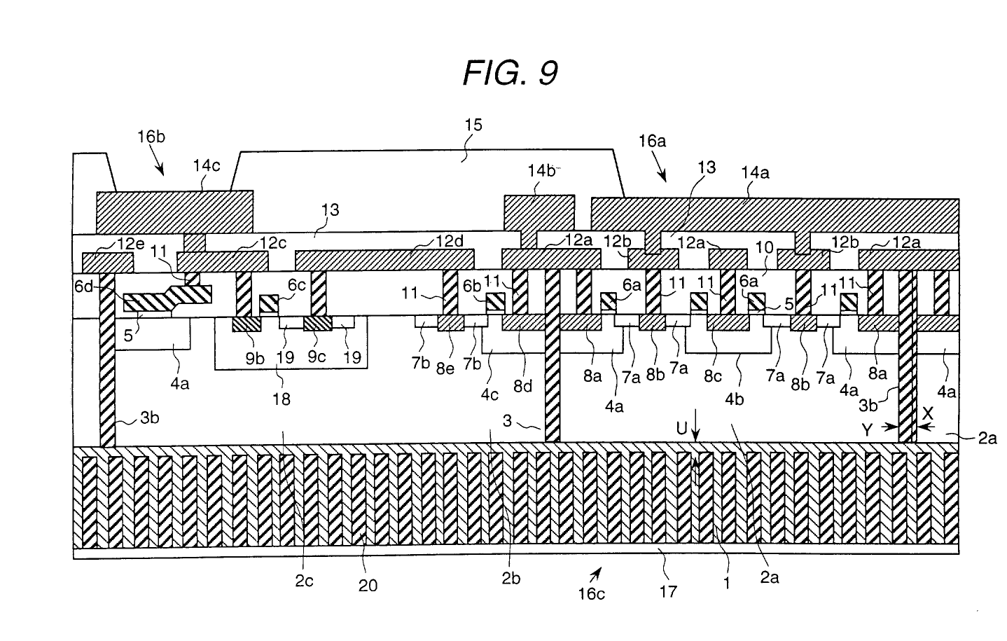

FIG. 9 is a circuit diagram of the present embodiment of a power semiconductor device. In the present embodiment, instead of the low resistance penetrating diffusion layer 3 of the first embodiment, the effective wafer thickness is thinned by forming a narrow-width and deep groove in the silicon chip through anisotropic etching, and embedding a plug 3b made of a metal such as tungsten or a metallic compound into the groove. In the case of the present embodiment, the on resistance per unit area can be further reduced because the dimension Y can be narrowed when the dimension X is constant, similarly to the fifth embodiment, and the resistance can be furthermore reduced because the specific resistance of the low resistance perforating zone 3a is reduced.

Further, in the present embodiment, as a method of reducing the resistance of the p-type semiconductor substrate 1, the groove is formed in the silicon, and a metal such as copper or aluminum or a metallic compound 20 is embedded into the groove. In the present embodiment, the insufficient portion in thinning the silicon thickness is compensated by lowering of the resistance by using the metal or the metallic compound 20. The present embodiment can made the effective thickness U of the semiconductor substrate 1 (the thickness of the semiconductor substrate in a portion where the metal or the metallic compound 20 is not inserted) thinner than 20 m, and particularly, the present embodiment is effective in a case where the substrate resistance component of a power transistor difficult to reduce the substrate resistance such as an SiC substrate is reduced.

Although in FIG. 9 the metal or the metallic compound 20 is embedded in the thin etched grooves, the same effect can be obtained by etching only a part of the silicon chip, for example, only a portion just under the active zone to form grooves so as to prevent the semiconductor substrate from causing cracks, and then embedding the grooves with a conductive adhesive such as solder or a metal or a metallic compound at mounting the power semiconductor device.

While the present invention has been described in detail based on the preferred embodiments, it is to be understood that the present invention is not limited thereto and that various changes and modifications may be made in the present invention without departing from the scope thereof. For example, although the description has been made on the case that the packaging structure is a flat packaging structure, it is to be understood that the structure is not limited thereto and that, for example, a BGA (ball grid array) packaging structure and a flip chip structure which provide direct connection to a package, etch with a bump, etc. may be used. Further, the transistor is not limited to the power MOSFET, but may be a junction field effect transistor or an SIT or an MESFET. Furthermore, although the description has been made mainly on the case that the power semiconductor device is applied to the DC/DC power supply circuit, it is to be understood that the structure is not limited thereto and that the power semiconductor device is applied to other kinds of power supply circuits.

As having been described above, according to the present invention, it is possible to materialize a power MOSFET which is low in capacity, low in on-resistance and low in parasitic impedance. Therefore, there are effects in cost reduction of the element and in improvement of the efficiency of a power supply device using the power MOSFET.

What is claimed is:

1. A power supply apparatus having an upper arm power semiconductor device, a lower arm power semiconductor device, and a control circuit for turning ON/OFF said upper arm and lower arm power semiconductor devices, wherein:
either one of said upper arm power semiconductor device or said lower arm power semiconductor device sets up low resistance semiconductor zones for the drain of the power transistor, low resistance semiconductor zones for the source of the power semiconductor and gate electrodes on a first plane of the semiconductor chip, and external terminals for the source are connected to a low resistance substrate zone which is a second plane of said semiconductor chip;
low resistance ohmic connection is formed by providing a low resistance perforating conductive area between said source low resistance semiconductor zones and said low resistance substrate zone; and
a plurality of said low resistance drain zones are provided between first low resistance semiconductors zones for the source arranged near said low resistance perforating conductive zone out of said source low resistance semiconductor zones, second low resistance semiconductor zones for the source arranged apart from said low resistance perforating conductive area being provided between said low resistance drain zones.

2. A power supply apparatus according to claim 1, wherein:
said power transistor is a power MOSFET.

3. A power supply apparatus according to claim 1, wherein:
said power transistor is a junction type field effect transistor.

4. A power supply apparatus according to claim 1, wherein:
on the same chip as said power transistor, an external gate terminal for turning ON said power transistor, a pre-driver transistor which is used to turn OFF said power transistor, and an external input terminal for controlling said pre-driver transistor are installed.

5. A power supply apparatus having an upper arm power semiconductor device, a lower arm power semiconductor device and a control circuit for turning ON/OFF said upper arm and lower arm power semiconductor devices, wherein:
either one of said upper arm power semiconductor device or said lower arm power semiconductor device sets up a low resistance semiconductor zone for the drain of the power transistor, a low resistance semiconductor zone for the source of the power semiconductor and gate electrodes on a first plane of the semiconductor chip, and external terminals for the source are connected to a low resistance substrate zone which is a second plane of said semiconductor chip;
low resistance ohmic connection is formed by providing a low resistance perforating conductive zone between said source low resistance semiconductor zone and said low resistance substrate zone; and
said source low resistance semiconductor zone and said low resistance perforating conductive zone are ohmic-connected through a conductive wire provided in a zone separated by an insulation layer on said drain low resistance semiconductor zone.

6. A power supply apparatus according to claim 5, wherein:
said power transistor is a power MOSFET.

7. A power supply apparatus according to claim 5, wherein:
said power transistor is a junction type field effect transistor.

8. A power supply apparatus according to claim 5, wherein
on the same chip as said power transistor, an external gate terminal for turning ON said power transistor, a pre-driver transistor which is used to turn OFF said power transistor, and an external input terminal for controlling said pre-driver transistor are installed.

9. A power supply apparatus having an upper arm power semiconductor device, a lower arm power semiconductor device and a control circuit for turning ON/OFF said upper arm and lower arm power semiconductor devices, wherein:
either one of said upper arm power semiconductor device or said lower arm power semiconductor device sets up low resistance semiconductor zones for the drain of the power transistor, low resistance semiconductor zones for the source of the power semiconductor and a gate electrode on a first plane of the semiconductor chip, and external terminals for the source are connected to a low resistance substrate zone which is a second plane of said semiconductor chip;
low resistance ohmic connection is formed by providing a low resistance perforating conductive zone between said source low resistance semiconductor zones and said low resistance substrate zone; and
a drain outer terminal is formed in a zone separated by an insulating layer on a transistor active zone in which said gate electrode is formed.

10. A power supply apparatus according to claim 9, wherein:
said power transistor is a power MOSFET.

11. A power supply apparatus according to claim 9, wherein:
said power transistor is a junction type field effect transistor.

12. A power supply apparatus according to claim 9, wherein:
on the same chip as said power transistor, an external gate terminal for turning ON said power transistor, a pre-driver transistor which is used to turn OFF said power transistor, and an external input terminal for controlling said pre-driver transistor are installed.
